(19) United States
(12) Patent Application Publication
(10) Pub. No.: US 2018/0023774 A1
(43) Pub. Date: Jan. 25, 2018

(54) PHOTOVOLTAIC SYSTEM AND METHOD FOR UTILIZING ENERGY OF LIGHT EMITTED BY LIGHT FIXTURE

(71) Applicant: IOT Technology Corporation, Zhubei City (TW)

(72) Inventor: Kai-Jie CHEN, Taipei City (TW)

(21) Appl. No.: 15/654,227

(22) Filed: Jul. 19, 2017

(30) Foreign Application Priority Data
Jul. 22, 2016 (TW) 105123153

(51) Int. Cl. F21S 9/03; H01L 31/048; H01L 31/02; H05B 37/02; H01L 31/054

(52) U.S. Cl. CPC F21S 9/037; H05B 37/0209; H01L 31/054; H01L 31/02021; H01L 31/048

(57) ABSTRACT

A photovoltaic system includes an electronic device and a switch device. The electronic device includes a photovoltaic (PV) module, a transmitter and a control module. The PV module converts energy of light emitted by a light fixture into electric power and stores the same therein. The control module transmits a signal through the transmitter when it is determined that an amount of the electric power stored in the PV module is below a threshold. The switch device electrically connected between the light fixture and a socket. In response to receiving the signal from the receiver, the switch device provides mains electricity from the socket to the light fixture to turn on the light fixture to thereby allow charging of the PV module.

### CROSS-REFERENCE TO RELATED APPLICATION

This application claims priority to Taiwanese Patent Application No. 105123153 filed on Jul. 22, 2016.

### FIELD

The disclosure relates to a photovoltaic (PV) system, and a method that is adapted for utilizing energy of light emitted by a light fixture and that is implemented by the PV system.

### BACKGROUND

A conventional wireless burglar alarm system usually includes magnetically actuated sensors mounted on a door or a window of a house for detecting housebreaking, and an alarm to warn of burglaries. The conventional burglar alarm system may further report an intrusion into the house to a security center such as a security company or a police station. However, maintaining such burglar alarm system is inconvenient; for example, exchanging batteries of the magnetically actuated sensors is time consuming. Additionally, in order to apply Internet of things (IoT) technology to the conventional burglar alarm system, more sensors for detecting temperature, humidity, atmospheric pressure, concentration of carbon monoxide and/or smoke are required and thus consume more battery power. As a consequence, maintenance of such burglar alarm system would be even more troublesome.

### SUMMARY

Therefore, an object of the present disclosure is to provide a photovoltaic system and a method for utilizing energy of light emitted by a light fixture to generate electric power.

According to one aspect of the present disclosure, a photovoltaic system utilizing energy of light emitted by a light fixture includes an electronic device and a switch device. The electronic device includes a photovoltaic (PV) module, a transmitter and a control module. The PV module is for converting the energy of the light emitted by the light fixture into electric power and for storing the electric power therein. The control module is electrically connected to the PV module and the transmitter, and is configured to determine an amount of the electric power stored in the PV module and transmit a turn-on signal through the transmitter when it is determined by the control module that the amount of the electric power stored in the PV module is below a threshold. The switch device is configured to be electrically connected to the light fixture, and includes a receiver for receiving the turn-on signal, and a switch unit electrically connected to the receiver, configured to be electrically connected between the light fixture and a socket, and receiving mains electricity from the socket. In response to receiving the turn-on signal from the receiver, the switch unit is configured to be in a conductive state to provide mains electricity to the light fixture so as to turn on the light fixture to emit light to thereby allow charging of the PV module.

According to another aspect of the present disclosure, a method for utilizing energy of light emitted by a light fixture is to be implemented by a photovoltaic system and a light fixture. The photovoltaic system includes an electronic device that includes a photovoltaic (PV) module, a transmitter and a control module, and a switch device that includes a receiver and a switch unit. The PV module converts the energy of the light emitted by the light fixture into electric power and stores the electric power therein. The switch unit is electrically connected to the receiver, is configured to be electrically connected between the light fixture and a socket, and receives mains electricity from the socket.

The method includes: a) determining, by the control module, whether an amount of the electric power stored in the PV module is below a threshold; b) when the determination made in step a) is affirmative, transmitting, by the control module, a turn-on signal through the transmitter and to be received by the switch unit via the receiver; c) relaying, by the switch unit, mains electricity from the socket to the light fixture by switching to a conductive state in response to receipt of the turn-on signal from the receiver so as to turn on the light fixture to emit light to thereby allow charging of the PV module.

### BRIEF DESCRIPTION OF THE DRAWINGS

Other features and advantages of the present disclosure will become apparent in the following detailed description of the embodiments with reference to the accompanying drawings, of which:

FIG. 1 is a schematic block diagram of a photovoltaic system utilizing energy of light emitted by a light fixture according to an embodiment of the present disclosure;

FIG. 2 illustrates a schematic circuit diagram of a switch device of the photovoltaic system electrically connected between a socket and the light fixture; and

FIG. 3 is a schematic circuit diagram of a modification of the switch device electrically connected between the socket and the light fixture; and

FIG. 4 is a flow chart of a method for utilizing energy of light emitted by a light fixture according to an embodiment of this disclosure.

### DETAILED DESCRIPTION

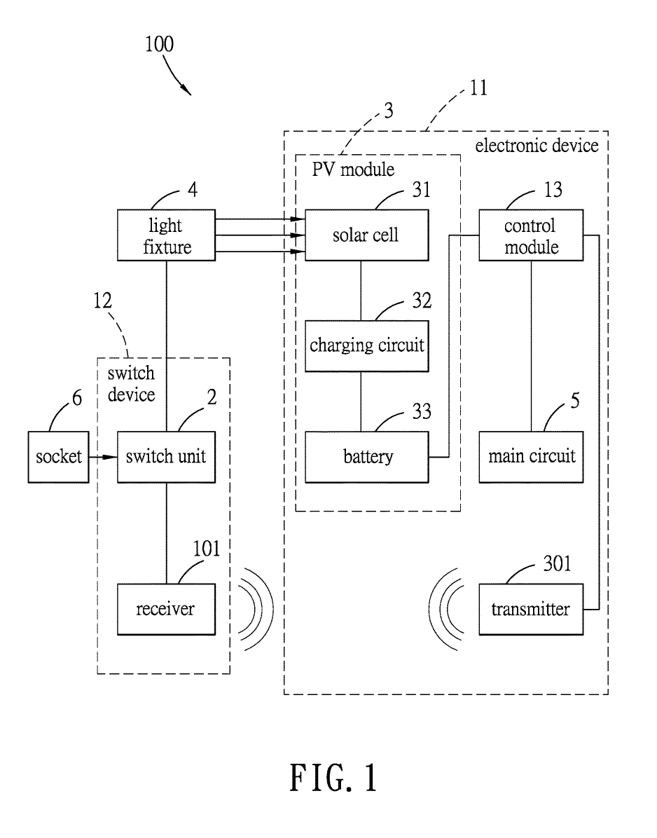

Referring to FIG. 1, a photovoltaic (PV) system 100 utilizing energy of light emitted by a light fixture 4 according to an embodiment of this disclosure is shown. The PV system 100 includes an electronic device 11 and a switch device 12. The electronic device 11 includes a PV module 3, a main circuit 5, a transmitter 301 and a control module 13.

In this embodiment, the PV module 3 includes a solar cell 31, a charging circuit 32 and a battery 33. The solar cell 31 is for example a copper indium gallium diselenide (CIGS) film solar cell capable of converting energy of light emitted by the light fixture 4 into electric power. The charging circuit 32 is electrically connected to the solar cell 31 and the battery 33, and is for storing the electric power converted by the solar cell 31 in the battery 33.

The main circuit 5 is controlled by the control module 13 and is electrically connected to and powered by the battery 33 through the control module 13. The main circuit 5 may be a detecting circuit, an electronic lock circuit, or an environment sensing circuit that requires continuous power supply. In this embodiment, the main circuit 5 is a detecting circuit mounted on a door or a window of a house for detecting break-in through the door or the window. In another embodiment, the main circuit 5 is an environment sensing circuit for sensing ambient temperature, humidity, atmospheric pressure, concentration of carbon monoxide or smoke around the house. In yet another embodiment, the main circuit 5 is an electronic lock circuit serving as an electronic lock to be mounted to the door or the window of the house, and the present disclosure is not limited in this respect.

The switch device 12 is electrically connected to the light fixture 4, and includes a receiver 101 and a switch unit 2. The switch unit 2 is electrically connected to the receiver 101, is electrically connected between the light fixture 4 and a socket 6, and receives mains electricity from the socket 6.

The control module 13 is electrically connected to the battery 33 of the By module 3 and the transmitter 301, and is configured to determine an amount of the electric power stored in the battery 33 and to transmit a turn-on signal through the transmitter 301 when determining that the amount of the electric power stored in the battery 33 is below a threshold. The receiver 101 of the switch device 12 is for receiving the turn-on signal from the transmitter 301.

In response to receiving the turn-on signal from the receiver 101, the switch unit 2 switches to a conductive state to provide mains electricity to the light fixture 4 so as to turn on the light fixture 4 to emit light. Subsequently, the PV module 3 converts energy of the light emitted by the light fixture 4 into electric power and allows charging of the battery 33 (i.e., increasing the amount of electric power stored in the battery 33). By this way, the main circuit 5 may continue to be powered by the battery 33 and function properly.

On the other hand, the control module 13 of the electronic device 11 transmits a turn-off signal through the transmitter 301 when it is determined by the control module 13 that the battery 33 of the PV module 3 is fully charged (i.e., the amount of the electric power stored in the battery 33 has reached its maximum). In response to receipt of the turn-off signal through the receiver 101, the switch unit 2 switches to a non-conductive state to stop providing mains electricity to the light fixture 4, so the light fixture 4 is turned off and stops emitting the light. In this embodiment, the transmitter 301 and the receiver 101 are implemented by Bluetooth low energy (BLE) communication interfaces and the disclosure is not limited in this respect.

The control module 13 may be implemented by any circuit/circuitry that is configured or programmed to carry out the aforementioned functionalities in this disclosure. The switch unit 2 may be implemented by an electrically operated switch, but is not limited thereto.

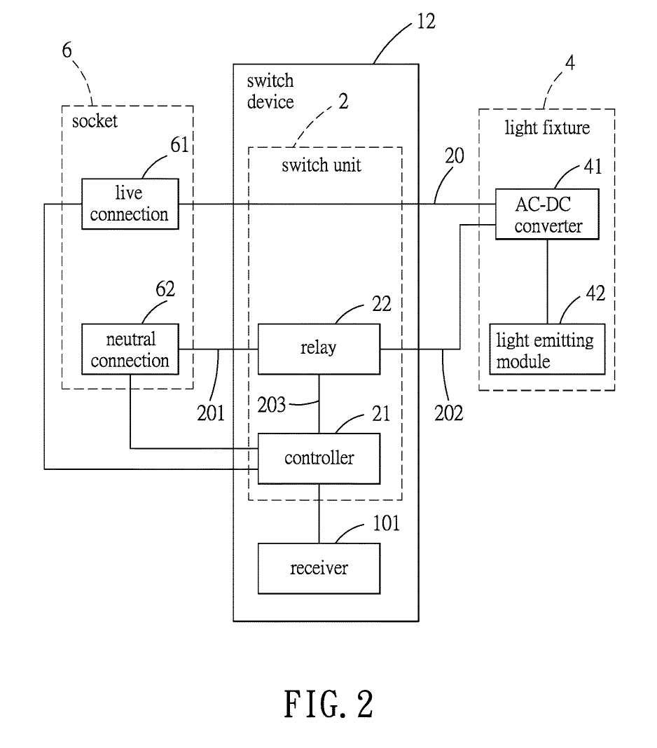

Referring to FIG. 2 in combination with FIG. 1, further detailed structures of the light fixture 4 and the switch unit 2 are described below. The light fixture 4 includes an alternating current to direct current (AC-DC) converter 41 that has two input terminals, and a light emitting module 42. The switch unit 2 includes a connecting wire 20, a controller 21 and a relay 22. The connecting wire 20 directly and electrically connects one of the input terminals of the AC-DC converter 41 to a live connection 61 of the socket 6. The relay 22 includes a first pin 201, a second pin 202 and a third pin 203. The first pin 201 is electrically connected to a neutral connection 62 of the socket 6, the second pin 202 is electrically connected to the other one of the input terminals of the AC-DC converter 41, and the third pin 203 is electrically connected to the controller 21. The controller 21 is electrically connected to the neutral connection 62 and the live connection 61 of the socket 6, is electrically connected to the receiver 101, and drives the relay 22 to allow the socket 6 to supply mains electricity to the light fixture 4 in response to receipt of the turn-on signal from the receiver 101. As a consequence of being supplied with mains electricity, the light emitting module 42 emits light to be converted into electric power by the PV module 3. The light emitting module 42 may for example include at least one light emitting diode (LED).

Note that in other embodiments, the light fixture 4 may be part of the photovoltaic system 100, and the disclosure is not limited in this respect.

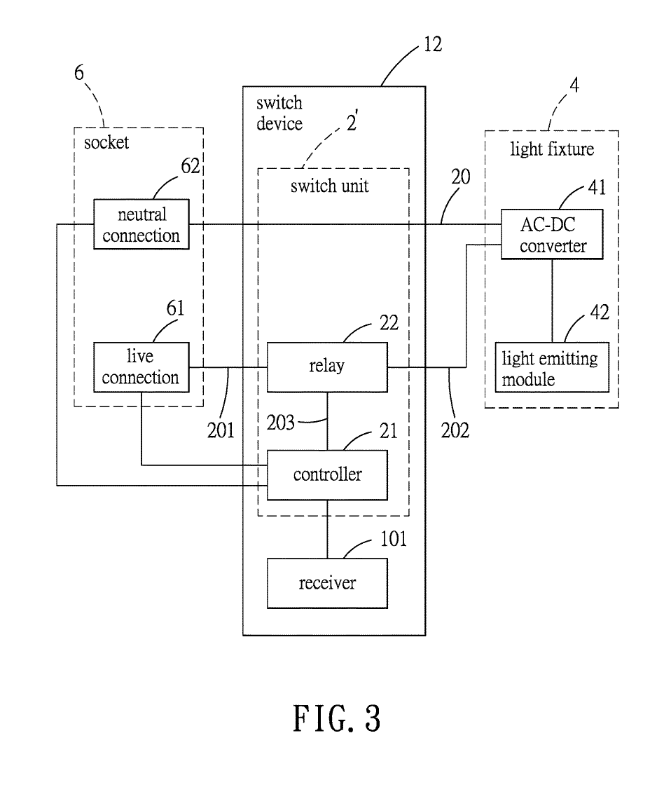

Referring to FIG. 3, a modification of the switch unit 2′ is depicted. In this modification, the switch unit 2′ includes a connecting wire 20, a controller 21 and a relay 22. The connecting wire 20 directly and electrically connects one of the input terminals of the AC-DC converter 41 to the neutral connection 62 of the socket 6. The relay 22 includes a first pin 201, a second pin 202 and a third pin 203. The first pin 201 is electrically connected to the live connection 61 of the socket 6, the second pin 202 is electrically connected to the other one of the input terminals of the AC-DC converter 41 and the third pin 203 is electrically connected to the controller 21.

The controller 21 is electrically connected to the live connection 61 and the neutral connection 62 of the socket 6, is electrically connected to the receiver 101, and drives the relay 22 to allow the socket 6 to supply mains electricity to the light fixture 4 in response to receipt of the turn-on signal from the receiver 101. In this embodiment, the relay 22 is a solid-state relay.

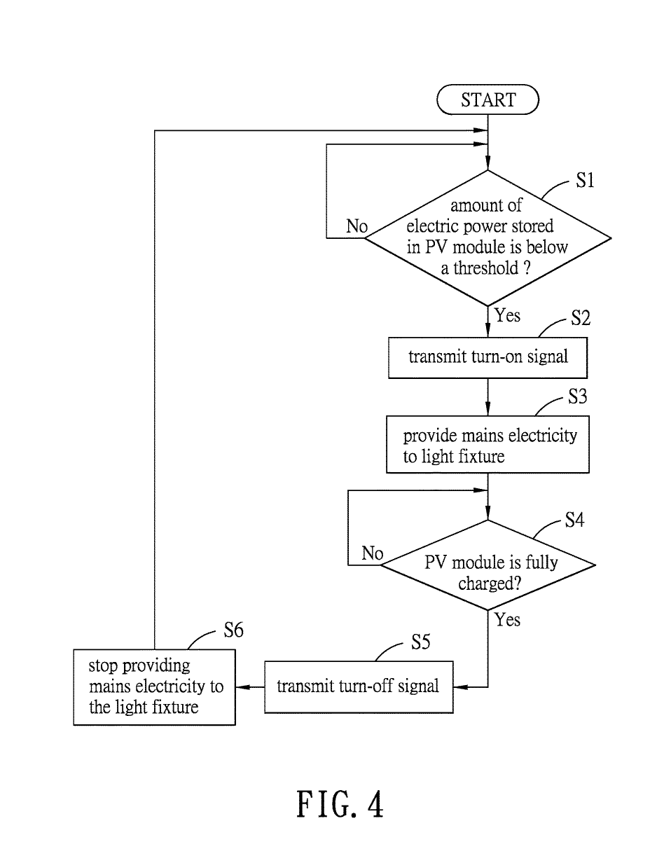

Now referring to FIG. 4, a method for utilizing energy of light emitted by the light fixture 4, which is to be implemented by the photovoltaic system 100 described above, is described below.

In step S1, the control module 13 determines whether the amount of the electric power stored in the battery 33 of the PV module 3 is below a threshold.

When the determination made in step S1 is affirmative, a flow of the method goes to step S2; otherwise, the flow returns to step S1. In step S2, the control module 13 transmits a turn-on signal through the transmitter 301 to be received by the switch unit 2 via the receiver 101. Subsequent to step S2, in step S3, the switch unit 2 switches to a conductive state upon receipt of the turn-on signal, so that the socket 6 provides mains electricity to the light fixture 4 to turn on the light fixture 4. By this way, the light fixture 4 emits light to thereby allow charging of the battery 33 of the PV module 3.

Subsequent to step S3, in step, S4, the control module 13 determines whether the battery 33 is fully charged. When the determination made in step S4 is affirmative, in step S5, the control module 13 transmits a turn-off signal through the transmitter 301 to be received by the switch unit 2 via the receiver 101. When the determination made in step S4 is negative, step S4 is performed once again. In step S6, the switch unit 2 switches to a non-conductive state upon receipt of the turn-off signal so the socket 6 stops providing mains electricity to the light fixture 4. Finally, the flow returns to step S1.

To sum up, in the present disclosure, by virtue of the control module 13 that determines the amount of electric power stored in the battery 33 and controls provision of mains electricity to the light fixture 4 through the switch unit 2, the PV module 3 can convert energy of the light emitted by the light fixture 4 into electric power and store the electric power in the battery 33. Thus, the amount of the electric power stored in the battery 33 can be kept larger than the threshold, and the battery 33 is capable of continuously providing electric power to the main circuit 5 at all times. As a result, maintenance of the main circuit 5 such as exchanging batteries of the main circuit 5 as described in the conventional burglar alarm system is not required to thereby reduce cost of maintenance of the electronic device 11.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A photovoltaic system utilizing energy of light emitted by a light fixture, said photovoltaic system comprising:
an electronic device including
a photovoltaic module for converting the energy of the light emitted by the light fixture into electric power and for storing the electric power therein,
a transmitter, and
a control module electrically connected to said PV module and said transmitter, and configured to determine an amount of the electric power stored in said PV module and to transmit a turn-on signal through said transmitter when it is determined by said control module that the amount of the electric power stored in said PV module is below a threshold; and
a switch device configured to be electrically connected to the light fixture, and including
a receiver for receiving the turn-on signal from said transmitter, and
a switch unit electrically connected to said receiver, configured to be electrically connected between the light fixture and a socket, and receiving mains electricity from the socket,
wherein, in response to receiving the turn-on signal from said receiver, said switch unit is configured to be in a conductive state to provide mains electricity to the light fixture so as to turn on the light fixture to emit light to thereby allow charging of said PV module.

2. The photovoltaic system as claimed in claim 1, wherein said control module of said electronic device transmits a turn-off signal through said transmitter when it is determined by said control module that said PV module is fully charged, and said switch unit is configured to be in a non-conductive state to stop providing mains electricity to the light fixture in response to receiving the turn-off signal through said receiver.

3. The photovoltaic system as claimed in claim 2, wherein said electronic device further includes a main circuit electrically connected to and controlled by said control module.

4. The photovoltaic system as claimed in claim 3, wherein said main circuit is one of a detecting circuit, an electronic lock circuit, and an environment sensing circuit.

5. The photovoltaic system as claimed in claim 1, the light fixture including an alternating current to direct current (AC-DC) converter that has two input terminals, wherein said switch unit includes:
a connecting wire configured to directly and electrically connect one of the input terminals of the AC-DC converter to a live connection of the socket;
a relay including a first pin, a second pin and a third pin, said first pin adapted to be electrically connected to a neutral connection of the socket, said second pin adapted to be electrically connected to the other one of the input terminals of the AC-DC converter; and
a controller adapted to be electrically connected to the neutral connection and the live connection of the socket, electrically connected to said receiver and said third pin of said relay, and configured to drive said relay to allow the socket to supply mains electricity to the light fixture in response to receiving the turn-on signal from said receiver.

6. The photovoltaic system as claimed in claim 1, the light fixture including an alternating current to direct current (AC-DC) converter that has two input terminals, wherein said switch unit includes:
a connecting wire configured to directly and electrically connect one of the input terminals of the AC-DC converter to a neutral connection of the socket;
a relay including a first pin, a second pin and a third pin, said first pin adapted to be electrically connected to a live connection of the socket, said second pin adapted to be electrically connected to the other one of the input terminals of the AC-DC converter; and
a controller adapted to be electrically connected to the neutral connection and the live connection of the socket, electrically connected to said receiver and said third pin of said relay, and configured to drive said relay to allow the socket to supply mains electricity to the light fixture in response to receiving the turn-on signal from said receiver.

7. The photovoltaic system as claimed in claim 6, wherein said relay is a solid-state relay.

8. The photovoltaic system as claimed in claim 1, further comprising the light fixture.

9. The photovoltaic system as claimed in claim 1, wherein said PV module includes a battery for storing electric power therein.

10. The photovoltaic system as claimed in claim 9, wherein said PV module further includes a solar cell for converting the energy of the light emitted by the light fixture into the electric power, and a charging circuit electrically connected to said solar cell and said battery and for storing the electric power converted by said solar cell in said battery.

11. A method for utilizing energy of light emitted by a light fixture implemented by a photovoltaic system and the light fixture, the photovoltaic system including an electronic device that includes a photovoltaic (PV) module, a transmitter and a control module, and a switch device that includes a receiver and a switch unit, the photovoltaic (PV) module converting the energy of the light emitted by the light fixture into electric power and storing the electric power therein, the switch unit electrically connected to the receiver, configured to be electrically connected between the light fixture and a socket, and receiving mains electricity from the socket, the method comprising:
a) determining, by the control module, whether an amount of the electric power stored in the PV module is below a threshold;
b) when the determination made in step a) is affirmative, transmitting, by the control module, a turn-on signal through the transmitter to the switch unit via the receiver;
c) relaying, by the switch unit, mains electricity from the socket to the light fixture by switching to a conductive state in response to receipt of the turn-on signal from the receiver so as to turn on the light fixture to emit light to thereby allow charging of the PV module.

12. The method as claimed in claim 11, further comprising determining, by the control module, whether the PV module is fully charged,
when the determination made above is affirmative, transmitting, by the control module through the transmitter, a turn-off signal to the switch unit via the receiver to configure the switch unit to be in a non-conductive state to stop providing mains electricity to the light fixture.
